(19) United States
(12) Patent Application Publication
(10) Pub. No.: US 2011/0232846 A1
(43) Pub. Date: Sep. 29, 2011

(54) MAGNETIC FIELD GENERATOR FOR MAGNETRON PLASMA

(75) Inventors: Koji MIYATA, Takefu-shi (JP); Kazuyuki TEZUKA, Nirasaki-shi (JP); Koichi TATESHITA, Nirasaki-shi (JP); Hiroo ONO, Nirasaki-shi (JP); Kazuya NAGASEKI, Nirasaki-shi (JP); Shinji HIMORI, Nirasaki-shi (JP)

(73) Assignee: SHIN-ETSU CHEMICAL CO., LTD., Tokyo (JP)

(21) Appl. No.: 13/154,016

(22) Filed: Jun. 6, 2011

Related U.S. Application Data
(62) Division of application No. 10/525,240, filed on May 13, 2005, now abandoned.

(30) Foreign Application Priority Data
Aug. 21, 2002 (JP) 2002-241124
Aug. 21, 2002 (JP) 2002-241250
Aug. 22, 2002 (JP) 2002-241802
Feb. 24, 2003 (JP) 2003-046097

(51) Int. Cl. H01L 21/3065; C23C 16/511

(52) U.S. Cl. 156/345.42; 118/723 MA

(57) ABSTRACT

Disclosed is a magnetic field generator for magnetron plasma. The magnetic field generator is provided with a plurality of magnetic segments, and generates a predetermined multi-pole magnetic field around the periphery of a workpiece substrate within a process chamber. The strength of the multi-pole magnetic field is controlled so that the state of the multi-pole magnetic field is matched different plasma processes. Further, the pattern of the multi-pole magnetic field can be changed so as to match different sizes of the substrate.

### CROSS REFERENCE TO RELATED APPLICATIONS

This application is a divisional of U.S. patent application Ser. No. 10/525,240, filed May 13, 2005, which is a national stage entry of International Application No. PCT/JP2003/010583, filed Aug. 21, 2003, which claims priority from Japanese Patent Application No. 2002-241124, filed Aug. 21, 2002, Japanese Patent Application No. 2002-241250, filed Aug. 21, 2002, Japanese Patent Application No. 2002-241802, filed Aug. 22, 2002, and Japanese Patent Application No. 2003-046097, filed Feb. 24, 2003, the contents of all of which are incorporated herein by reference in their entirety.

### TECHNICAL FIELD

The present invention relates to a magnetic field generator for generating magnetron plasma which acts on a work piece substrate such as a semiconductor wafer so as to perform etching process and the like.

### BACKGROUND TECHNOLOGY

In the field of manufacturing semiconductor devices, a semiconductor treatment apparatus is known for generating magnetron plasma in a process chamber. The plasma thus generated is allowed to act on a work piece such as a semiconductor wafer positioned within the process chamber whereby a desired treatment process such as etching and film forming, etc. is performed.

In order to attain satisfactory results, it is necessary to maintain the plasma in a state optimized for a particular process. For this purpose, the magnetron plasma processing apparatus is provided with a magnetic field generator that controls plasma in a desired state.

Japanese Patent Publication No. 2001-338912, by way of example, discloses a magnetic field generator that generates a multi-pole magnetic field using a plurality of permanent magnets arranged circularly outside the treatment chamber so that their north and south poles alternate with each other. With this arrangement, a multi-pole magnetic field is generated at the periphery of a semiconductor wafer placed in the chamber, while no magnetic field is generated above the semiconductor wafer. An even number of magnetic poles are provided, usually eight to thirty-two, depending on the required field strength at the periphery of the wafer.

It is known in the art to utilize a plasma treatment apparatus wherein etching proceeds on a semiconductor wafer using multi-pole magnetic field generated at the periphery of the wafer and maintaining the state of the plasma by appropriately controlling the strength of the multi-pole magnetic field. However, according to the research of the inventors of the instant application it was discovered that there are two contradictory instances in terms of etch rate uniformity across the wafer's surface. In one instance the etch rate uniformity is increased in the presence of multi-pole magnetic field, while in the other instance the etch rate uniformity is increased in the absence of multi-pole magnetic field.

When etching is performed on a silicon dioxide film, the etch rate uniformity is more improved in the presence of a multi-pole magnetic field relative to the absence of a multi-pole magnetic field. In this case, the absence of multi-pole magnetic field causes the etch rate to go high at the wafer's center area and low at the wafer's peripheral area.

On the contrary, when etching is performed on an organic low-dielectric (low-K) film and the like, the etch rate uniformity on the wafer's surface was more improved in the absence of multi-pole magnetic field than in the presence of a multi-pole magnetic field. In this case, the presence of a multi-pole magnetic field causes the etch rate to go low at the wafer's center area and high at the wafer's peripheral region.

If electromagnets are used to generate a multi-pole magnetic field, the start/stop control of the magnetic field generation can be carried out with ease. However, the use of electromagnets is disadvantageous due to their high power consumption and bulkiness. For these reasons, the current practice is to employ permanent magnets. However, a large loading machine is required to mount and dismount permanent magnets on and from the processing apparatus to perform the start/stop control, and accordingly, this involves a long time to operate the machine, resulting in a lowering of the overall working efficiency of semiconductor processing.

On the other hand, the size of semiconductor wafers has increased to such an extent that their diameter is now twelve inches and wafers of different sizes coexist, while the multi-pole magnetic field needs to be controlled according to the particular size of each wafer. It is thus impossible to consistently use the prior art magnetic field generator for treating all wafers, regardless of their sizes. Hence there exists a need for a magnetic field generator capable of adaptively controlling the multi-pole magnetic field according to any size of substrates.

The present invention is thus intended to solve the above-mentioned problems. More specifically, the present invention provides a magnetic field generator for generating a multi-pole magnetic field that can be controlled so as to meet the particular needs depending on a kind of plasma processing and the particular sizes of semiconductor wafers.

### DISCLOSURE OF THE INVENTION

The present invention relates to a magnetic field generator for magnetron plasma, which generator is provided outside of a process chamber (or vacuum chamber) in which a work piece substrate is positioned and comprises a plurality of magnetic segments for generating a multi-pole magnetic field along the circumference of the work piece substrate. The present invention is characterized in that the multi-pole magnetic field can be controlled in terms of the strength thereof.

Further, the present invention is characterized in that part of the magnetic segments is rotatably mounted so that their magnetized directions are controllable, the rest of the permanent magnets being fixedly mounted. As an alternative, the magnetized directions of the above-mentioned fixedly mounted magnetic segments are oriented in circumferential directions relative to the center of the process chamber.

Further, the magnetic field generator is provided with an upper ring-shaped magnetic field generating mechanism and a lower ring-shaped magnetic field generating mechanism, and each of the upper and lower ring-shaped magnetic field generating mechanisms is provided with the magnetic segments each of which is rotatable about an axis extending to the center of the upper and lower ring-shaped magnetic field mechanisms.

Additionally, the present invention comprises an electrically conductive ring provided between the process chamber and the magnetic field generator for magnetron plasma, and the ring is provided in a manner to be rotated.

Still further, the strength of the multi-pole magnetic field within the process chamber is controlled by varying the number of poles of the multi-pole magnetic field.

### BRIEF DESCRIPTION OF THE DRAWINGS

FIG. 1 is a diagram for schematically illustrating an apparatus for use in semiconductor wafer etching, to which a magnetic field generator according to the present invention is applicable.

FIG. 2 is a schematic diagram for describing a magnetic field generator which is used in the apparatus shown in FIG. 1, which generator relates to a first embodiment of a first inventive step of the present invention.

FIG. 3 is a diagram for describing rotations of the magnetic segments which form part of the magnetic field generator of FIG. 2.

FIG. 4 is a diagram for describing rotations of the magnetic segments which form part of the magnetic field generator of FIG. 2.

FIG. 5 is a graphic representation for describing the states of the magnetic field strength within the vacuum chamber according to the first embodiment of the first inventive aspect of the present invention.

FIG. 6 is a graphic representation for describing a relationship between etch rate variations across a semiconductor wafer's surface and the magnetic field, according to the first embodiment of the first inventive aspect of the present invention.

FIG. 7 is a graphic representation for describing a relationship between etch rate variations across a semiconductor wafer's surface and the magnetic field, according to the first embodiment of the first inventive aspect of the present invention.

FIG. 8 is a graphic representation for describing a relationship between etch rate variations across a semiconductor wafer's surface and the magnetic field, according to the first embodiment of the first inventive aspect of the present invention.

FIG. 9 is a diagram for describing a second embodiment of the first inventive aspect of the present invention.

FIG. 10 is a diagram for describing a magnetic field generator which is given for the purpose of comparison with the magnetic field generator according to the embodiments of the first inventive aspect of the present invention.

FIG. 11 is a drawing for describing effects derived from a magnetic ring which is used in the magnetic field generator according to the embodiments of the first inventive aspect of the present invention.

FIG. 12 is a diagram for describing a magnetic field generator according to a third embodiment of the first inventive aspect of the present invention.

FIG. 13 is a schematic diagram for describing a second inventive aspect of the present invention.

FIG. 14 is a diagram for describing rotations of the magnetic segments which form part of the magnetic field generator of FIG. 13, according to a first embodiment of the second inventive aspect of the present invention.

FIG. 15 is a diagram for describing a second embodiment of the second inventive aspect of the present invention.

FIGS. 16(a) and (b) are diagrams for describing a third embodiment of the second inventive aspect of the present invention.

FIG. 17 is a schematic diagram for describing a plasma processing apparatus to which a third inventive aspect is applicable, and corresponds to FIG. 1.

FIG. 18 is a diagram for further describing the embodiments of the third inventive aspect of the present invention.

FIG. 19 is a diagram for describing a relationship between a rotation of an electrically conductive ring shown in FIGS. 17-18 and the magnetic field strength within the vacuum chamber.

FIG. 20 is a diagram for exemplifying a relationship between etch rates across a semiconductor wafer surface and a magnetic field, according to the embodiment of the third inventive aspect of the present invention.

FIG. 21 is a diagram for exemplifying a relationship between etch rates across a semiconductor wafer surface and a magnetic field, according to the embodiment of the third inventive aspect of the present invention.

FIG. 22 is a diagram for exemplifying a relationship between etch rates across a semiconductor wafer surface and a magnetic field, according to the embodiment of the third inventive aspect of the present invention.

FIG. 23 is a diagram for describing a first embodiment of a fourth inventive aspect of the present invention.

FIG. 24 is a diagram for describing a variant of the first embodiment of the fourth inventive aspect of the present invention.

FIG. 25 is a diagram for describing another variant of the first embodiment of the fourth inventive aspect of the present invention.

FIG. 26 is a diagram for describing still another variant of the first embodiment of the fourth inventive aspect of the present invention.

FIG. 27 is a diagram for describing a second embodiment of the fourth inventive aspect of the present invention.

### BEST MODES OF THE INVENTION

In the following, the present invention will be described with reference to the accompanying drawings.

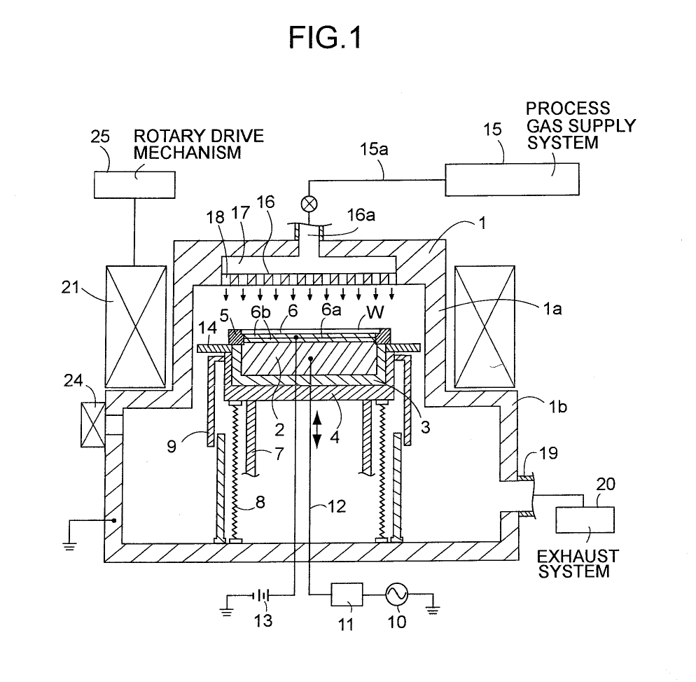

FIG. 1 schematically illustrates a magnetic field generator for magnetron plasma generation in accordance with the present invention, which generator is applied to a plasma etching apparatus for performing etch onto a semiconductor wafer. In FIG. 1, a vacuum chamber 1, which is made of aluminum (for example), serves to function as a plasma treatment space. The vacuum chamber 1 is substantially a cylindrical shape appearance, and is comprised of an upper portion 1a and a lower portion 1b with a stepwise portion therebetween. The vacuum chamber 1 is electrically grounded, and the upper portion 1a is configured such as to be smaller in terms of diameter relative to the lower portion 1b. Within the vacuum chamber 1 is a support table (susceptor) 2 that holds a semiconductor wafer W with its principle surface facing upwards.

The support table 2, typically formed of aluminum, is positioned on a support base 4 electrically isolated by an insulator 3 such as ceramics. Further, a focus ring 5 formed either of conductive or non-conductive material, is secured to the upper circumference of the support table 2.

An electrostatic chuck 6 is provided on the surface of support table 2 to hold the wafer W in a fixed position by electrostatic attraction. The chuck 6 includes an electrode 6a between insulators 6b, the electrode 6a being coupled to a direct current power source 13. When the electrode 6a is impressed with a dc voltage, the semiconductor wafer W is attracted to the support table 2 under Coulomb's force and held in position.

The support table 2 is provided with a refrigerant conduit (not shown) for circulating refrigerant, and further provided with a gas supplier (also not shown) for introducing helium gas to the wafer's lower surface as an effective thermal transfer means between the wafer W and the refrigerant, whereby the semiconductor wafer W is maintained at a desired temperature.

The support table 2 and the support base 4 can be adjusted in elevation by means of a ball screw mechanism a part of which is illustrated by a ball screw 7, and a driving portion at the lower part of the support base 4 is covered with a stainless steel (SUS) bellows 8 the outside of which is surrounded by a bellows cover 9.

A power feed line 12, which is used to supply high frequency electric power, is connected to the center area of the support table 2. To the power feed line 12 is also coupled a high frequency source 10 and a matching box 11. The high frequency power source 10 generates high frequency electric power in the range between 13.56 MHz and 150 MHz (preferably between 13.56 MHz and 100 MHz). By way of example, 100 MHz electric power is supplied to the support table 2.

Further, in order to increase an etch rate, it is preferable to superimpose two high frequencies one of which is for generating plasma and the other is for pulling ions among plasma. It is typical to use a high frequency power source (not shown) for ion pulling (bias voltage control), which frequency range is between 500 kHz and 13.56 MHz. The frequency of 3.2 MHz is preferred for etching silicon dioxide and 13.56 MHz is preferred for etching polysilicon or organic films.

On the outer side of the focus ring 5 is a baffle plate 14, which is electrically connected to the vacuum chamber 1 via the support base 4 and the bellows 8. A shower head 16, which is grounded, is attached to the ceiling over the support table 2 in the vacuum chamber 1, in a manner to be in parallel with and opposite to the support table 2. Therefore, the support table 2 and the shower head 16 are made to operate as a pair of electrodes.

Many gas ejection holes 18 are provided in the shower head 16, above which a gas inlet port 16a is provided. A gas diffusion space 7 is formed between the shower head 16 and the ceiling of vacuum chamber 1. The gas inlet port 16a communicates via a gas supply duct 15a to a gas supply system 15 that supplies reaction and diluted gases for etching.

As a reaction gas, halogen group (fluoric and chloric groups), and hydrogen gas and the like, for example, can be used. As a diluted gas, argon and helium gases can be used as is typically used in the field of technology in question. In an etching process, the process gas(es) as mentioned above is supplied from the gas supply system 15, via the conduit 15a and the gas inlet port 16a, into the gas diffusion space 17 over the shower head 16, where the gas is ejected through the gas ejection holes 18 and used to implement etching of a film formed on the surface of semiconductor wafer W.

A gas exhaust port 19 is provided at the sidewall of the lower part 1b of vacuum chamber 1, and communicates with a gas exhaust system 20 which is used to maintain the vacuum chamber 1 at a desired negative pressure level by operating a vacuum pomp. Further, the lower part 1b of the vacuum chamber 1 is provided at a higher vertical position of its sidewall with a gate valve 24 for introducing a semiconductor wafer into, and withdrawing it out of, the vacuum chamber 1.

Surrounding the upper part 1a of vacuum chamber 1 is a ring-shaped magnetic field generator 21 which is arranged in a concentric relationship with the vacuum chamber 1 so as to generate a multi-pole magnetic field around a processing space between the support table 2 and the shower head 16. This magnetic field generator 21 is rotatable at a predetermined speed around the vacuum chamber 1 using a rotary drive mechanism 25. In the instant specification, a magnetic field generator may interchangeably be referred to as a magnetic field generating mechanism.

The following is a description of the magnetic field generator 21 according to the first embodiment of the first aspect of the present invention.

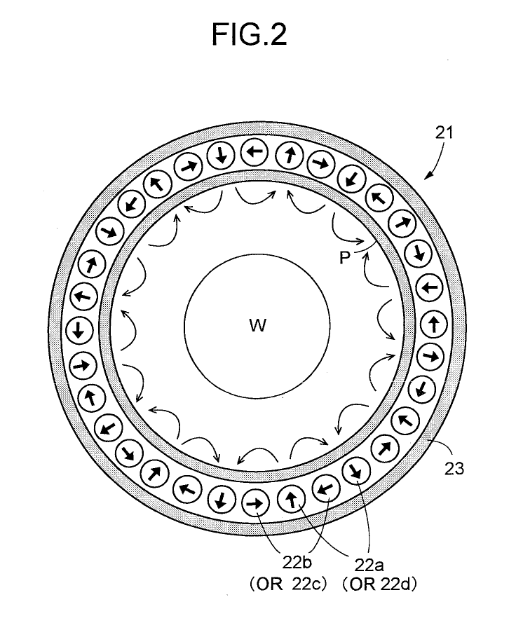

As shown in FIG. 2, the magnetic field generator 21 is comprised of a plurality of magnetic segments 22a (may be referred to as first magnetic segments) and a plurality of magnetic segments 22b (may be referred to as second magnetic segments 22b), all of which are supported by a support member (not shown) and the total number of the segments 22a and 22b counts thirty-two in this particular case. The magnetic segments 22a are arranged such that they alternate with the segments 22b and such that the magnetic poles thereof which direct toward the vacuum chamber 1 becomes S, N, S, N, . . . . The magnetic segments 22b are arranged such that they alternate with the segments 22a and such that their magnetic field directions are opposite to those formed in the vacuum chamber 1 along the circumferential directions thereof. Note that the arrowhead of each magnetic segment indicates its north pole. Preferably, all magnetic segments 22a and 22b are surrounded by a magnetic member 23. In the following description, the magnetic segments 22a and 22b may be referred to using a reference numeral 22.

In the case shown in FIG. 2, the magnetic segments 22b, which are provided alternately with the magnetic segments 22b, have their poles whose directions are alternately oriented to opposite radial directions. On the other hand, the magnetic segments 22b have their poles whose directions are fixed and oriented to the directions opposite to those of the magnetic field formed along the circumferential directions of the vacuum chamber 1. As a result, the magnetic lines of force as illustrated are formed, in the vacuum chamber 1, between the magnetic segments 22a which are radially magnetized and arranged alternately with the magnetic segments 22b. A multi-pole magnetic field of intensity of 0.02 to 0.2 T (220 to 2000 G), preferably, 0.03 to 0.045 T (300 to 450 G) is produced in the vicinity of the inner sidewall of the vacuum chamber 1. In the center area of the wafer W the magnetic field intensity is reduced to a substantially zero value.

The intensity of the multi-pole magnetic field is regulated within a specified range to prevent flux leakage due to high magnetic field intensity, while preventing failure from confining plasma due to low magnetic field intensity. Since the required magnetic field intensity varies depending on the structure and the materials that constitute the magnetic field generator, the present invention is not to be limited to the above mentioned numerical values.

While the magnetic field at the center of the wafer W is preferably of zero Tesla value, the presence of some magnetic field is allowed in the area where the wafer is located if the strength of this magnetic field is not strong enough to cause some unfavorable effect on the etching process. In the case shown in FIG. 2, a magnetic field of strength less than 420 μT (4.2 G) is formed around the wafer, which is sufficient to confine plasma.

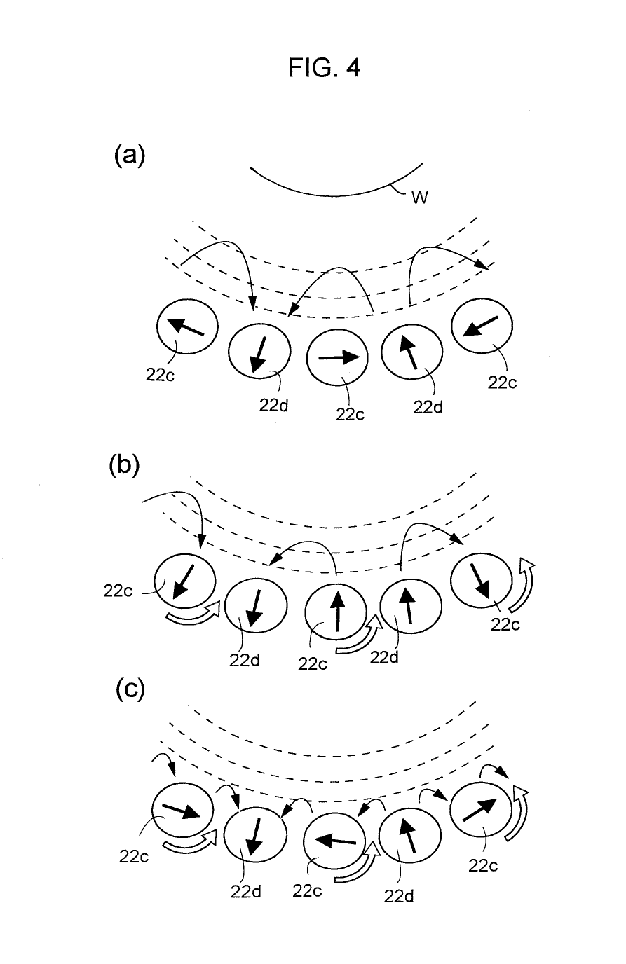

The magnetic segments 22a (or 22c in FIG. 4) of the magnetic field generator 21 can be made to rotate about their vertical center axis by means of a magnetic segment drive mechanism. On the other hand, the magnetic segments 22b (or 22d in FIG. 4) are fixed and thus are not rotatable.

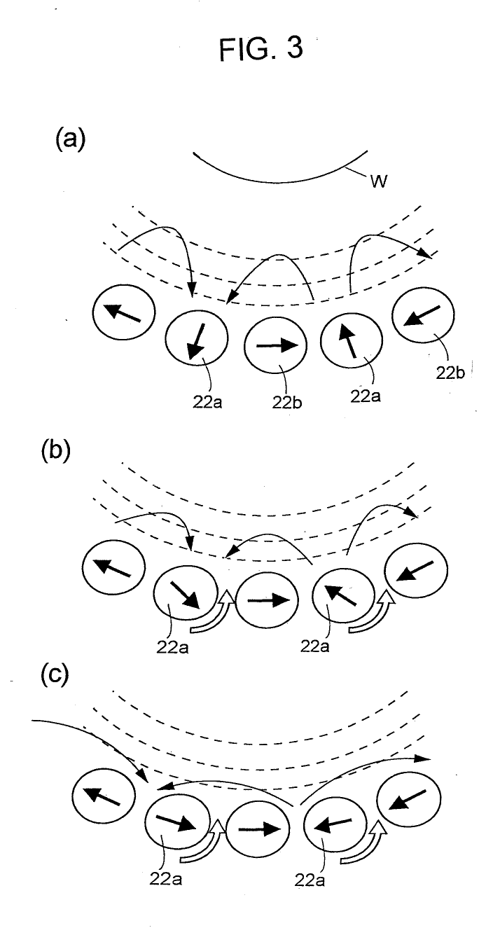

That is to say, the magnetic segments 22a are initially arranged such that the magnetic pole of each segment 22a is oriented towards the vacuum chamber 1 as shown in FIGS. 2 and 3(a). Thereafter, the magnetic segments 22a, which are positioned alternately with the magnetic segments 22b, rotate in synchronism with each other in the same direction as illustrated in FIGS. 3(b) and (c). FIG. 3(b) illustrates that each of the magnetic segments 22a rotates through 45-degree from the position shown in FIG. 3(a), while FIG. 3(c) illustrates that each of the magnetic segments 22a rotates through 90-degree from the position shown in FIG. 3(a). In the case shown in FIGS. 2, and 3(a) to 3(c), the angle of rotation of the magnetic segments 22a is variable in the range between zero and 95 degrees.

Further, as illustrated in FIGS. 2 and 4(a), the magnetic segments 22c are arranged alternately with the magnetic segments 22d. The magnetic segments 22c are initially positioned such that the magnetized directions thereof are oriented toward the circumferential directions, and then rotated in synchronism with each other such that their magnetized directions are oriented toward the radial directions as shown in FIG. 4(b). As an alternative, as shown in FIG. 4(c), each of the magnetic segments 22c can be rotated such that the magnetized direction is oriented toward the circumferential direction which is opposite to the case shown in FIG. 4(a). FIG. 4(b) illustrates that each of the magnetic segments 22c rotates through 90-degree from the position shown in FIG. 4(a), while FIG. 4(c) illustrates that each of the magnetic segments 22c rotates through 180-degree from the position shown in FIG. 4(a). In the case shown in FIGS. 2 and 4(a) to 4(c), the angle of rotation of the magnetic segments 22a is variable in the range between zero and 180 degrees.

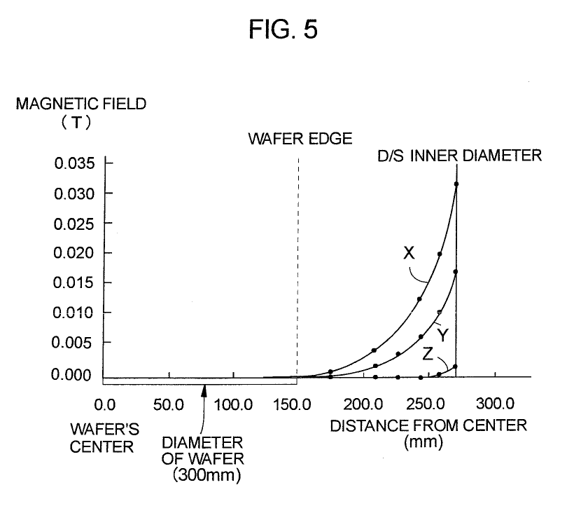

FIG. 5 is a graphic representation of the magnetic field strength within the vacuum chamber 1 measured as a function of the distance from the center of wafer W when the magnetic segments 22a are positioned as shown in FIG. 3(a) (denoted by curve X), when the magnetic segments 22a are respectively rotated through 45-degree as shown in FIG. 3(b) (denoted by curve Y), and when the magnetic segments 22a are respectively given a rotation of 90 degrees as shown in FIG. 3(c) (denoted by curve Z). Note that D/S inner diameter represents the inner diameter of a deposit shield attached to the inner wall of the vacuum chamber 1, and as such the D/S inner diameter is substantially equal to the inner diameter of the vacuum chamber 1.

As indicated by the curve X of FIG. 5, when the magnetic pole of each magnetic segment 22a is pointing toward the vacuum chamber 1, the multi-pole magnetic field reaches substantially the circumference of wafer W. On the other hand, as indicated by the curve Z, when each of the magnetic segments 22a is rotated 90 degrees, the strength of the multi-pole magnetic field within the vacuum chamber 1 is substantially reduced to zero. Further, as indicated by the curve Y, when each of the magnetic segments 22a is rotated 45 degrees, the strength of the multi-pole magnetic field within the vacuum chamber 1 is of an intermediate value of the above mentioned two cases.

As mentioned above, with the present embodiment, each of the magnetic segments 22a, which forms part of the magnetic field generator 21, synchronously rotates in the same direction. By rotating each magnetic segment 22a, a multi-pole magnetic field generation can be controlled such that the field is generated or reduced to substantially zero value around the semiconductor wafer W within the vacuum chamber 1.

Accordingly, when etching is to be performed on a silicon dioxide film or the like, a multi-pole magnetic field is generated around the semiconductor wafer W in the vacuum chamber 1 while performing the etching, whereby the uniformity of the etch rate across the surface of the semiconductor wafer W is able to be improved. On the contrary, when etching is performed on an organic low-dielectric film (Low-K) or the like, a multi-pole magnetic field is not generated around the semiconductor wafer W in the vacuum chamber 1 while performing the etching, whereby the uniformity of the etch rate on the surface of the semiconductor wafer W is able to be improved.

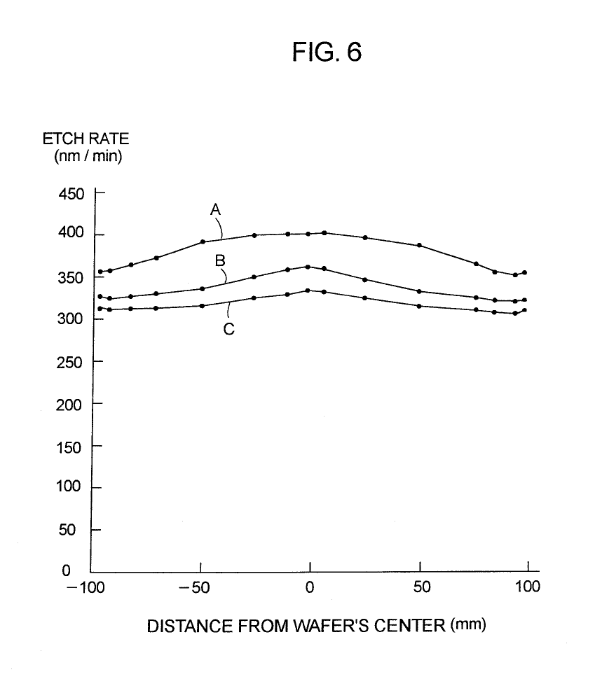

FIGS. 6 to 8 are graphic representations of experimental results of uniformities of etch rates measured as a function of the distance from the center of the semiconductor wafer W under different conditions. In each of FIGS. 6 to 8, the curve A indicates the results obtained in the absence of magnetic field in the vacuum chamber 1, the curve B indicating the results obtained in the presence of a multi-pole magnetic field of strength 0.03 T (300 G), and the curve C indicating the results obtained in the presence of a multi-pole magnetic field of strength 0.08 T (800 G).

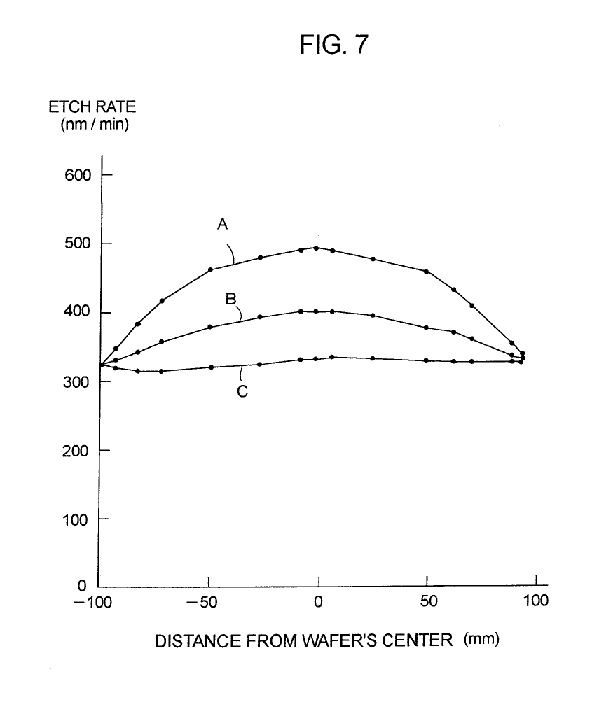

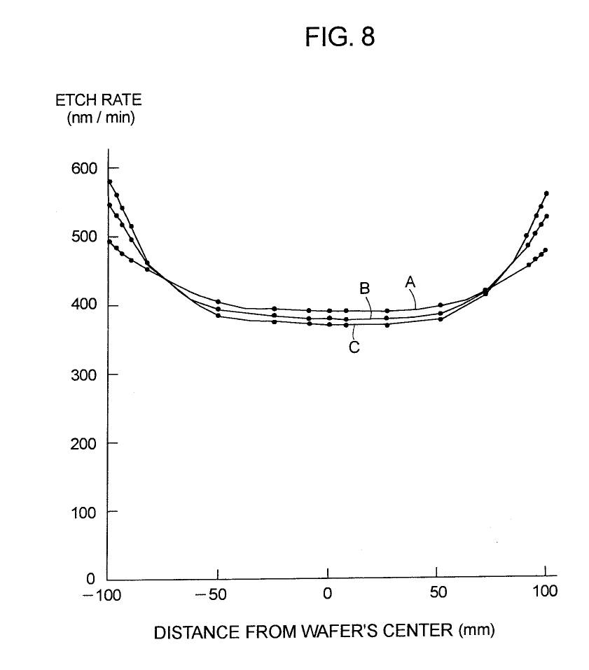

C₄F₈ gas was used for etching a silicon dioxide film to obtain the results shown in FIG. 6. CF₄ gas was used for etching a silicon dioxide film to obtain the results of FIG. 7, and a mixture of N₂ and H₂ gases was used for etching an organic low-dielectric film to obtain the results of FIG. 8. As indicated in FIGS. 6 and 7, in the case where the etching gas containing carbon (C) and fluorine (F) is used to etch the silicon dioxide film, it is understood that the etch rate uniformity over the surface of the wafer was able to be improved in the presence of a multi-pole magnetic field in the vacuum chamber 1. Further, as indicated in FIG. 8, when the mixture of N₂ and H₂ was used to etch the organic low-dielectric film, the etch rate uniformity over the surface of the wafer was able to be improved in the absence of the multi-pole magnetic field.

Therefore, in the first embodiment of the first inventive aspect, the multi-pole magnetic field can be easily controlled by rotating the magnetic segments 22a.

It is to be noted that the number of the magnetic segments 22a and 22b is not limited to thirty-two as in the case of FIG. 2. Further, the cross-section of each magnetic segment is not restricted to a circular and may take the form of square or polygon. However, since the magnetic segments 22a are arranged to be rotated, the segments 22a (22b) is preferred to take the circular cross-section because space saving can be achieved, which is able to reduce the size of the apparatus.

Still further, the magnetic segments 22a and 22b are not limited to specified ones, and may take the form of rare-earth magnets, ferrite magnets, or Alnico magnets, all of which are well known in the art.

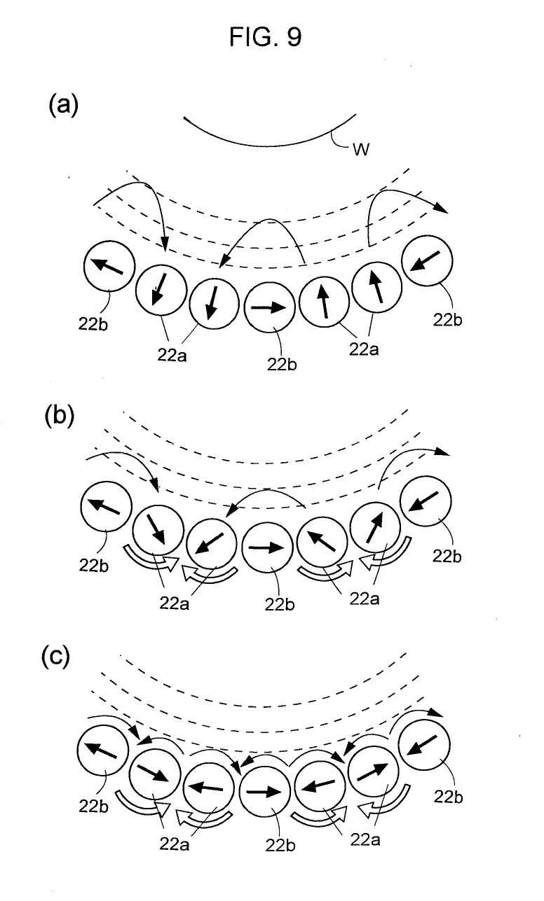

A second embodiment of the first inventive aspect will be described with reference to FIG. 9. As mentioned above, in the first embodiment of FIGS. 2 to 4, the total number of the magnetic segments 22 is set to thirty-two in order to generate the magnetic field with sixteen poles. Further, the magnetic segments 22a are provided alternately with the magnetic segments 22b, and are synchronously rotated in the same direction. On the contrary, in the second embodiment, forty-eight magnetic segments 22 are used in total. Of the forty-eight segments, thirty-two segments are rotatable, sixteen segments being fixed, and a magnetic field with sixteen poles is generated. That is to say, the second embodiment is substantially equal to the first embodiment other than the number of magnetic segments 22 which form magnetic circuits. Therefore, in the second embodiment, how to arrange the first and second magnetic segments can adaptively be determined depending on the magnetic field strength to be required. By way of example, the first magnetic segments may alternately be provided with the second magnetic segments, or, as an alternative, each of the first magnetic segments may be provided between grouped second magnetic segments (viz., each group includes a plurality of second magnetic segments which are adjacent with each other).

In accordance with the second embodiment of the first inventive scope of the present invention, by giving a rotation to the magnetic segments 22a such that they rotate synchronously as indicated by blank arrows in FIG. 9, it is possible to vary between a multi-pole magnetic field generation and no magnetic field generation in the vacuum chamber. In the case where the number of magnetic segments is increased as mentioned above, it is possible, when the segments are rotated 90 degrees, to further reduce the strength of the magnetic field around the wafer circumference to a level closer to zero.

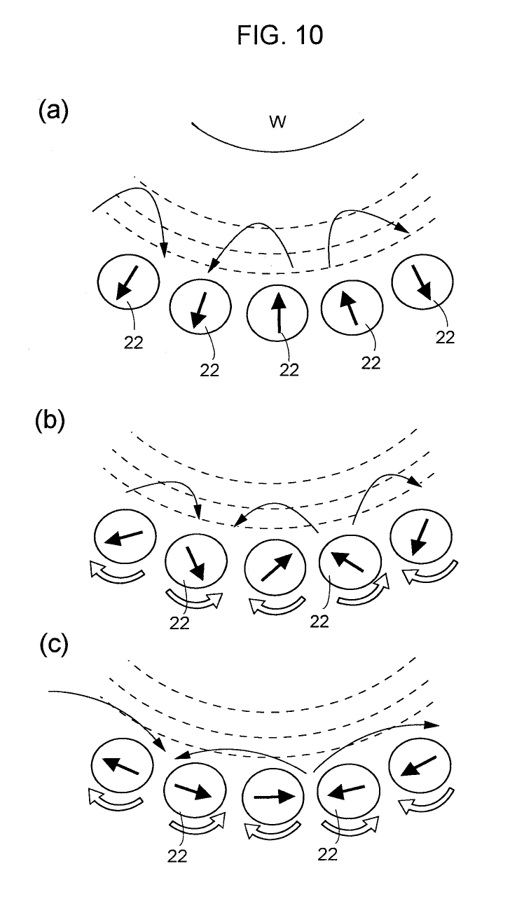

Meanwhile, as shown in FIG. 10 which is prepared for the purpose of comparison, in the case where all of the magnetic segments 22 of the magnetic field generator are rotated in the directions indicated by blank arrows, it is also possible to reduce the magnetic field strength to zero within the vacuum chamber. However, according to the first inventive aspect, the number of rotary magnetic segments can be reduced relative to the example shown in FIG. 10, and as such it is possible to simplify the apparatus. Additionally, since the embodiments of the first inventive aspect is better in terms of magnetic efficiency relative to the example presented for comparison, the strength of the multi-pole magnetic field can be increased by approximately 20% higher than that of the FIG. 10 arrangement. In other words, according to the embodiments of the first inventive aspect, it is possible to realize the same magnetic field strength with less number of magnets compared to the FIG. 10 arrangement.

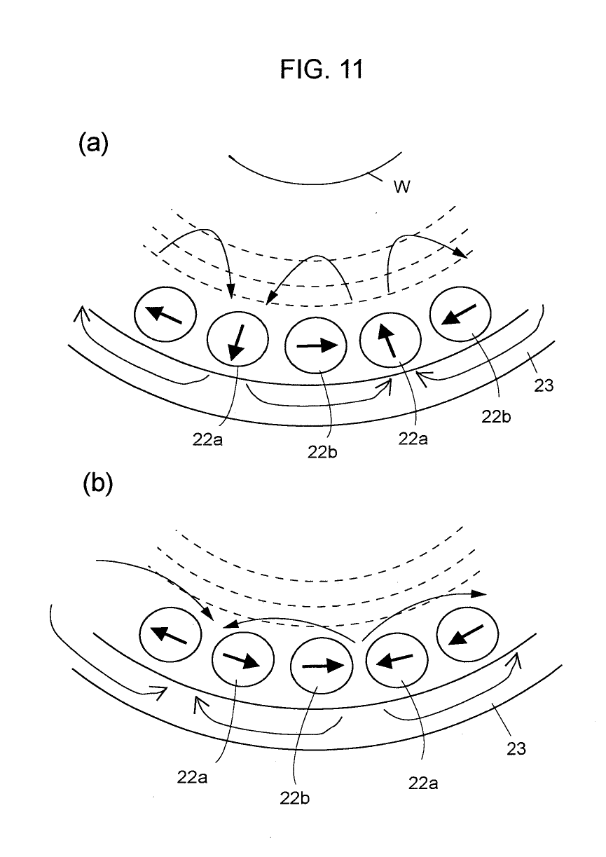

FIG. 11 is useful for explaining the effects derived from the presence of the magnetic ring 23 which is preferably provided outside of the magnetic segments. Suitable materials for the ring 23 are pure iron, carbon steel, iron-cobalt steel, stainless steel and the like. When the multi-pole magnetic field is established, the magnetic fluxes pass through the ring 23 such as to increase the magnetic field strength in the vacuum chamber. On the other hand, when the magnetic field is reduced to approximately zero in the vacuum chamber, the magnetic fluxes pass through the ring 23 such as to reduce the magnetic field strength in the vacuum chamber. As a result, the range of magnetic field strength variations can be increased with the provision of the ring 23.

The following is a description of the operation of the plasma etching process using the magnetic field generator of the present invention.

Initially, the gate valve 24 is opened to allow a semiconductor wafer to be introduced, via a load lock chamber (not shown) adjacent to the valve 24, by a loading machine (not shown) into the vacuum chamber 1 and placed on the support table 2 which is already lowered to a predetermined position. When a dc voltage is impressed on the electrode 6a of the electrostatic chuck 6, the semiconductor wafer W is secured to the support table 2 under Coulomb's force.

Thereafter, the loading machine is then withdrawn from the vacuum chamber 1, the gate valve 24 being closed, the support table 2 being raised to the higher position as indicated in FIG. 1 and the suction pump of exhaust system 20 being operated to decrease the pressure in the vacuum chamber 1 through the exhaust port 19.

When the pressure in the vacuum chamber 1 is dropped to a preset level, the gas supply system 15 is operated to admit a preselected gas(es) into the vacuum chamber 1 at a rate 100 to 1000 sccm (for example), after which the pressure within the vacuum chamber 1 is maintained at 1.33 to 133 Pa (10 to 1000 Torr), preferably 2.67 to 26.7 Pa (20 to 200 mTorr).

Under this condition, the high frequency power source 10 is operated to supply high frequency power of 100 to 3000 watts at frequency 13.56 MHz to 150 MHz (100 MHz by way of example) to the support table 2. In this case, a high frequency electric field is produced between the shower head (viz., upper electrode) 16 and the support table (viz., lower electrode) 2. As a result, the introduced gas is converted into plasma under the influence of the high frequency field, which plasma acts on the wafer W thereby to cause etching a predetermined portion(s) of the film deposited on the semiconductor wafer W.

As described above, each of the magnetic segments 22a is given a rotation of a specified angle, depending on the plasma process to be carried out, so as to orient the segments 22a to predetermined directions so that a multi-pole magnetic field is generated in the vacuum chamber 1 or is not generated therein.

The multi-pole magnetic field generated may cause localized erosions or scraping at the portions of the inner sidewall of the vacuum chamber 1, which portions correspond to the poles (as marked by the letter P in FIG. 2). In order to avoid the localized erosions, the magnetic field generator 21 is revolved about its vertical center axis by the rotary drive mechanism 25 so as to move the magnetic poles against the inner sidewall of the vacuum chamber 1.

At the end of the etching process, the high frequency power from the power source 10 is shut off, the support table 2 being lowered, and the semiconductor wafer W being taken out of the vacuum chamber 1 to the outside through the gate valve 24.

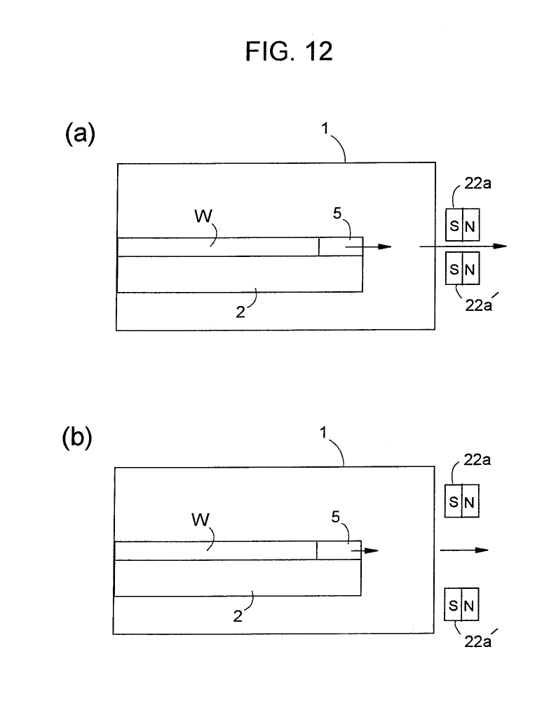

A third embodiment of the first inventive aspect will be described with reference to FIG. 12. In the instant embodiment, the ring-shaped magnetic field generator 21 is divided into two parts, one of which is an upper ring-shaped magnetic field generator and the other is a lower ring-shaped magnetic field generator. These upper and lower magnetic field generators are vertically movable such that the magnetic segments 22a and 22a′, which are respectively mounted on the upper and lower generators, can be brought close to each other, or can be moved away from each other. More specifically, when they are brought close to each other, the magnetic field strength increases as indicated by a long arrow in FIG. 12(a), and when they are moved away from each other, the field strength decreases as indicated by a short arrow as shown in FIG. 12(b). Although the second magnetic segments 22b and 22b′ are not illustrated in FIG. 12, it is understood from the foregoing description how to arrange these magnetic segments 22b and 22b′. As in the above-mentioned embodiments, some of the magnetic segments mounted on the upper and lower magnetic field generators are arranged to rotate. It is preferable to rotate the upper and lower magnetic field generators around the vacuum chamber 1 at a predetermined speed as in the above-mentioned embodiments by way of rotary drive mechanism 23 shown in FIG. 1.

As described in the foregoing description, the multi-pole magnetic field according to the first aspect of the present invention can easily be controlled and maintained in a desired condition in order to appropriately meet the needs of different plasma treatment processes.

The following is a description of a second aspect of the present invention.

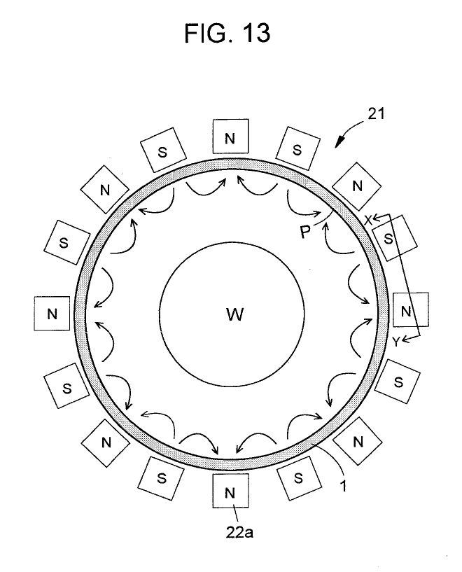

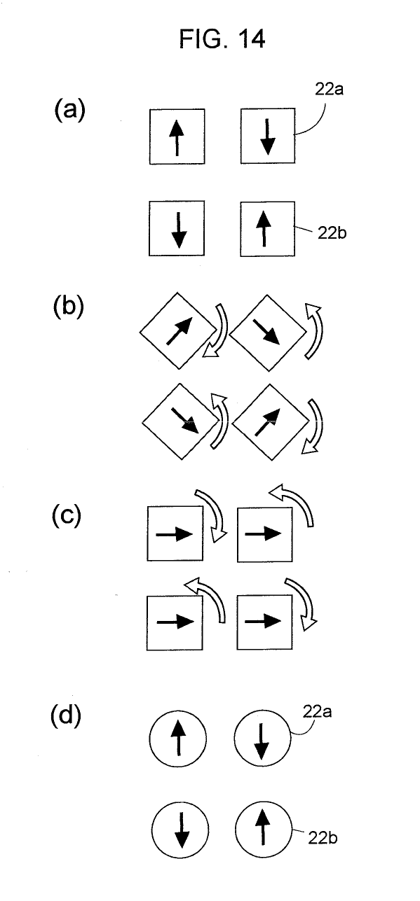

The magnetron plasma processing apparatus (for example, etching apparatus), to which the second inventive aspect is applicable, is identical to the apparatus already referred to with the first inventive aspect, and accordingly, the description thereof will be omitted. As illustrated in FIG. 13, the magnetic field generator according to the second inventive aspect, also designated by numeral 21 as in the first inventive aspect, comprises magnetic segments 22a (the number of which is sixteen in FIG. 13) which are held by a supporting means (not shown), and also comprises magnetic segments 22b which are not shown in FIG. 13. The segments 22b is equal to the segments 22a in number, and are respectively positioned below the corresponding segments 22a. FIGS. 14(a) to 14(c) are cross-sectional views taken along the line X-Y of FIG. 13. For the sake of simplicity, the magnetic segments 22a and 22b are in the shape of a square if taken along a horizontal plane and viewed from above, so that the sides of the square are assumed to be parallel to the X-Y and horizontal planes.

In the case shown in FIGS. 13 and 14(a), the directions of the adjacent magnetic segments 22a are vertically oriented with the poles thereof being opposite, and likewise, the directions of the adjacent magnetic segments 22b are vertically oriented with the poles thereof being opposite. Further, the upper and lower segments 22a and 22b are arranged such as to oppose with each other each with an identical pole. As seen from FIGS. 13 and 14(a), the magnetic segments 22a and 22b are respectively ring-likely arranged, and may be referred to as upper and lower magnetic field generators, respectively.

As in the case shown in FIGS. 13 and 14(a), the magnetic fluxes are formed between the adjacent segments, and a multi-pole magnetic field is generated within the vacuum chamber 1. In the instant case, the multi-pole magnetic field has magnetic field strength of 0.02 to 0.2 T (200 to 2000 G), preferably 0.03 to 0.045 T (300 to 450 G), in the vicinity of the inner wall of the chamber 1, and no magnetic field substantially exists in the center area of the magnetic wafer W.

The intensity of the multi-pole magnetic field is regulated within a specified range to prevent flux leakage due to high magnetic field intensity, while preventing failure from confining plasma due to low magnetic field intensity. Since the required magnetic field intensity varies depending on the structure and the materials that constitute the magnetic field generator, the present invention is not limited to the above mentioned numerical values. This applies to other embodiments of the present invention which will be described later.

While the magnetic field at the center of the wafer W is preferably of zero Tesla value, the presence of some magnetic field is allowed in the area where the wafer is located if the strength of this magnetic field is not strong enough to cause some unfavorable effect on the etching process. In the case shown in FIGS. 13 and 14(a), a magnetic field of strength less than 420 μT (4.2 G) is formed around the wafer, which is sufficient to confine plasma. This applies to other embodiments of the present invention which will be described later.

In the first embodiment of the second inventive step, the magnetic segments 22a and 22b of the magnetic field generator 21 are respectively rotatable about axes extending in the radial direction of the corresponding ring-like magnetic generators, which rotation is given by rotation drive mechanisms (not shown).

As shown in FIG. 14(a), the magnetic segments 22a and 22b are such that the magnetic poles thereof are oriented in vertical directions. The segments 22a adjacently arranged are rotated in opposite directions with each other, and likewise, the segments 22b adjacently arranged are rotated in opposite directions with each other, as shown in FIGS. 14(b) and 14(c). Further, the segments 22a and 22b, which are respectively arranged in the upper and lower magnetic field generators, rotates in opposite directions with each other as shown in FIGS. 14(b) and 14(c). FIGS. 14(b) and 14(c) respectively show two upper magnetic segments 22a and two lower magnetic segments 22b when they are rotated 45 degrees and 90 degrees relative to the initial orientations (FIG. 14(a)). The angle of orientation of magnetic segments 22a, 22b can be varied in the range between minimum of zero to a maximum of 90 degrees with respect to the initial angles in FIG. 14(a). FIG. 14(d) will be described later.

As described above, the multi-pole magnetic field, which is generated by the magnetic field generator of the first embodiment of the second inventive aspect, can easily be controlled and maintained in a desired condition by rotating the upper and lower magnetic segments 22a and 22b.

It is to be noted that the scope of the present invention is not limited to what is described above. That is, the each number of the magnetic segments 22a and 22b is not necessarily set to sixteen as shown in FIG. 13. Further, the cross-section of each magnetic segment may be either in the shape of a circular, a square or a polygon. However, in order to reduce the apparatus size, the circular cross-section is preferred because space saving can be achieved as shown in FIG. 14(d).

Further, the materials suitable for the magnetic segments 22a and 22b include rare-earth, ferrites and Alnico, which are well known in the art in the manufacture of permanent magnets.

As in the first aspect of the present invention, the magnetic field strength within the vacuum chamber was measured as a function of the distance from the center of wafer W in connection with the three cases: where the magnetic poles of each of the magnetic segments 22a and 22b are oriented in the vertical directions as shown in FIG. 14(a), where each of the magnetic segments 22a and 22b rotates 45 degrees as shown in FIG. 14(b), and where each of the magnetic segments 22a and 22b rotates 90 degrees as shown in FIG. 14(c). The same results were obtained as with the first inventive aspect indicated in FIG. 5. The curves X, Y and Z of FIG. 5 indicate the magnetic field strengths corresponding to FIGS. 14(a), 14(b) and 14(c), respectively.

Further, the etch rate uniformity over the semiconductor wafer W according to the first embodiment of the second inventive aspect was measured under the same conditions as described in the first inventive aspect with reference to FIGS. 6 to 8, and the same results were obtained which are identical to those as shown in FIGS. 6, 7 and 8.

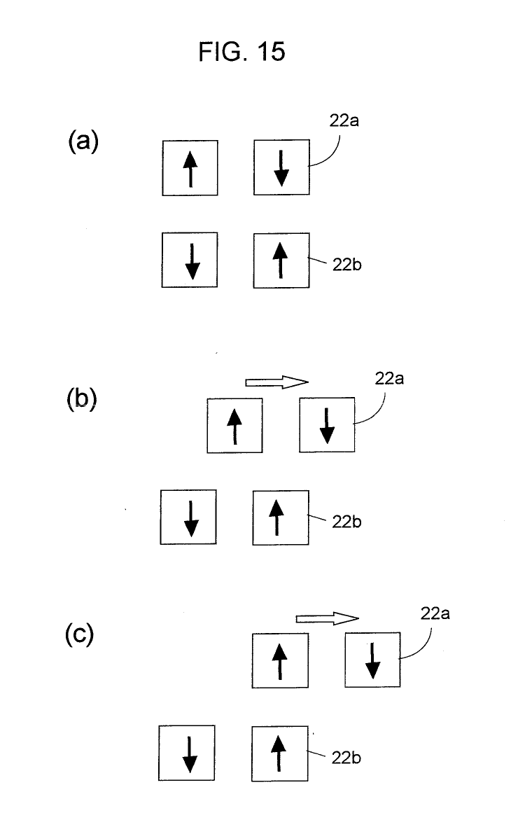

A second embodiment of the second inventive aspect will be described with referent to FIG. 15. In the instant embodiment, the magnetic field generator comprises upper and lower magnetic field generating portions (or mechanisms), each of which is configured to take the form of a ring or the like and which are independently rotatable about the vertical center axes thereof, respectively. It is therefore possible to change the mutual angular position of the upper and lower magnetic field generating portions. Accordingly, the upper and lower magnetic segments can be positioned such as to face the same magnetic poles thereof with each other as shown in FIG. 15(a), and also can be positioned such as to face the opposite magnetic poles thereof with each other as shown in FIG. 15(c).

In the case shown in FIG. 15(a), a multi-pole magnetic field is generated in the vacuum chamber 1 along the circumference of the semiconductor wafer W. In the case shown in FIG. 15(c), there exists substantially no magnetic field in the vacuum chamber 1. In the case of FIG. 15(b), a multi-pole magnetic field is generated which strength takes a medium value with respect to those in the cases shown in FIGS. 15(a) and 15(c). By independently rotating the upper and lower magnetic field generating portions about the vertical center axis thereof, the strength of the multi-pole magnetic field in the vacuum chamber 1 along the circumference of the semiconductor wafer W can be varied in the range between zero and maximum in the same way as in the first embodiment of the second inventive aspect. Note that, while mention has been made of an embodiment in which the upper and lower rings are both rotated, the present invention can be modified so that only one of the upper and lower rings is driven and the other is held in a stationary position.

A third embodiment of the second inventive aspect will be described.

According to this embodiment, the magnetic segments 22 (viz., magnetic field generator 21) are rotated so as to control a multi-pole magnetic field, which is identical to the above-mentioned embodiments of the second inventive aspect.

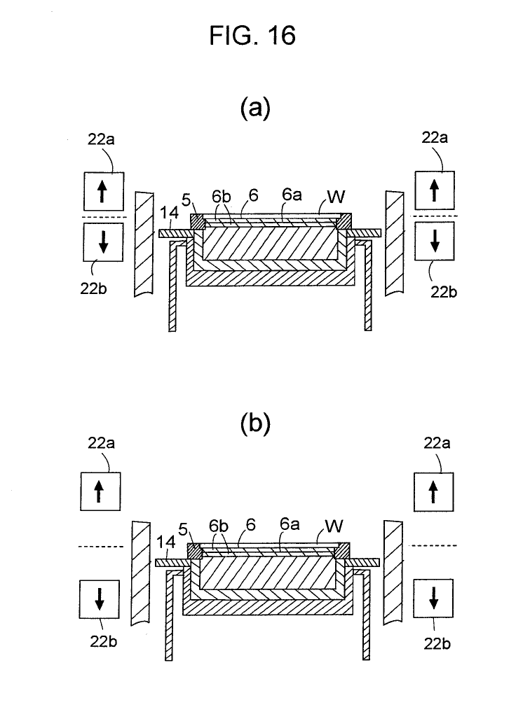

A shown in FIG. 16(a), according to the third embodiment of the second inventive aspect, the ring-shaped magnetic field generator 21 comprises upper and lower magnetic field generating portions (or mechanisms). However, in the present embodiment, the magnetic segments 22a and 22b, which are respectively mounted on upper and lower magnetic field generating portions, are vertically movable with respect to each other. As a result, the spacing between the upper ring and the lower ring can be varied. The amount of displacement between the upper and lower ring structures is up to one half of the inner diameter of the ring structure, preferably up to one third of the diameter of the ring structure. Note that the inner structure of the vacuum chamber 1 which is partially shown in FIG. 16 is identical to that shown in FIG. 1.

With this arrangement, when the upper and lower magnetic segments 22a and 22b are brought close to each other, a multi-pole magnetic field is generated in the vacuum chamber 1 near the circumference of the wafer W and when they are moved away from each other, no magnetic field substantially exists in the vacuum chamber 1.

As described above, the multi-pole magnetic field generated by the magnetic field generator embodying the second inventive aspect can be adaptively controlled and maintained with ease in a desired condition depending on different plasma processes.

A third inventive aspect will be described.

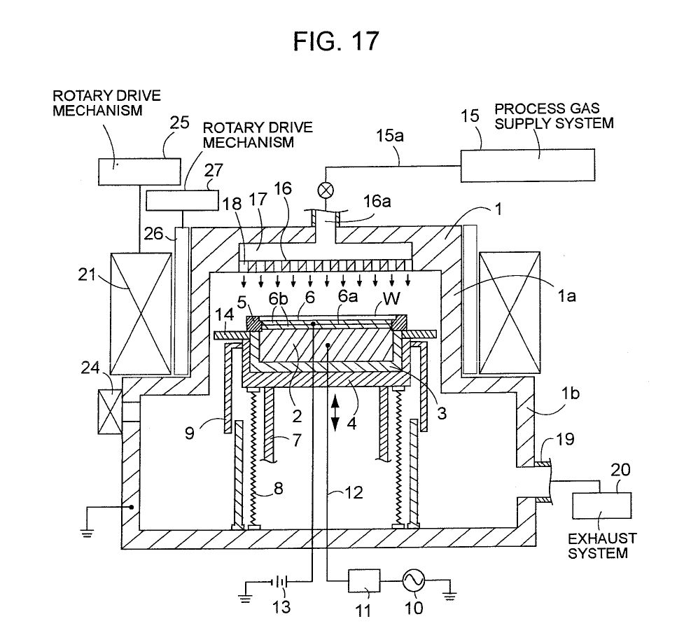

FIG. 17 is similar to FIG. 1 and differs therefrom in that a non-magnetic (such as aluminum) conductive ring 26 is provided between the magnetic field generator 21 and the vacuum chamber 1. Other than this, the remaining portions or member of FIG. 17 are identical to those of FIG. 1, and as such, the descriptions thereof will be omitted.

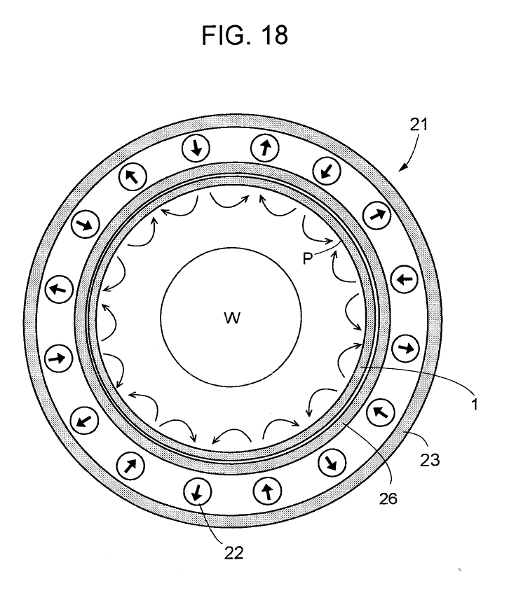

As shown in FIG. 18, the magnetic field generator 21 according to the third inventive aspect comprises a plurality of magnetic segments 22 (sixteen in this example) supported by a supporting mechanism (not shown). Their magnetic poles are oriented to the vacuum chamber 1 and alternately opposite. To increase the magnetic efficiency of the system, the magnetic segments 22 are surrounded by magnetic ring (iron for example) 23.

In the case as shown in FIG. 18, the adjacent magnetic segments 22 of the magnetic field generator 21 are such that they are directed in radial directions with their poles being opposite. Therefore, magnetic fluxes are formed between the adjacent magnetic segments 22 within the vacuum chamber 1 as shown in the figure. In the instant case, in the neighborhood of the periphery of the processing space, i.e., the space close to the inner sidewall of the vacuum chamber 1, the magnetic field is generated whose strength is 0.02 to 0.2 T (200 to 2000 G) by way of example, preferably 0.03 to 0.045 T (300 to 450 G), and in the center area of the semiconductor wafer W, a multi-pole magnetic field exists whose strength is reduced to a low level.

The reason why the intensity of the magnetic field is regulated to such a specified range as mentioned above comes from the fact that, if the magnetic field strength is too high, an undesirable magnetic flux leakage undesirably takes place, and on the contrary, if the strength is too low, no effective confinement of plasma may be attained. Since the required magnetic field intensity varies depending on the structure and the materials that constitute the magnetic field generator, the present invention is not to be limited to the above mentioned numerical values.

While the magnetic field at the center of the wafer W is preferably of zero Tesla value, the presence of some magnetic field is allowed in the area where the wafer W is located if the strength of this magnetic field is not strong enough to cause some unfavorable effect on the etching process. In the case of FIG. 18, a magnetic field of strength 420 μT (4.2 G) is generated which is sufficient to confine plasma.

In addition, according to the embodiment of the third inventive aspect, the non-magnetic conductive ring 26, which is made of aluminum or the like, is provided between the magnetic field generator 21 and the vacuum chamber 1. This ring 26 is driven by a rotary drive mechanism 27 so that it rotates at a predetermined speed (30 to 300 rpm, for example).

When the conductive ring 26 rotates, eddy currents are generated in the conductive ring 26 due to cross-linkage with the magnetic flux produced by the magnetic field generator 21. As a result, the strength of the magnetic field inside the conductive ring 26 is weakened in proportion to its speed of revolution.

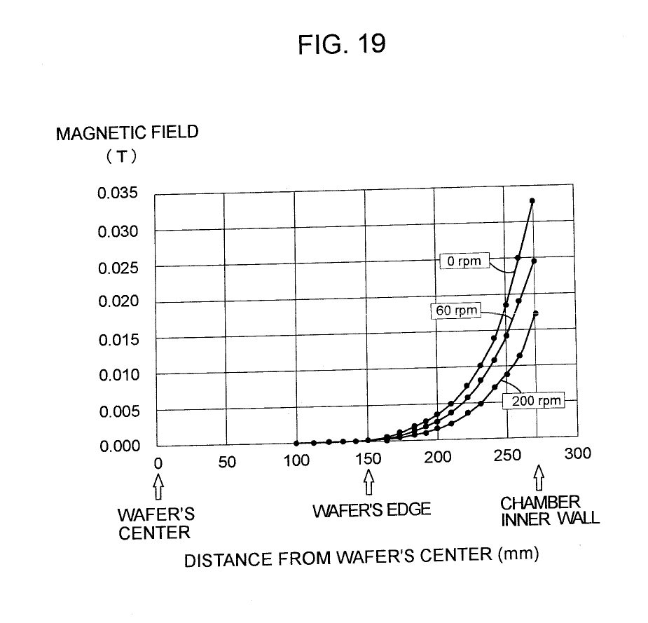

That is to say, it is possible to control the magnetic field strength within the vacuum chamber 1 by varying the rotating speed of the conductive ring 26. FIG. 19 is a graphic representation of the strength of the magnetic field plotted as a function of the distance from the center of semiconductor wafer W when the conductive ring 26 is driven at speeds of 0, 60 and 200 rpm. As indicated in FIG. 19, the magnetic field strength is varied from 0.033 T (330 G) when the ring is stationary to 0.017 T (170 G) when the ring is rotated at 200 rpm.

As mentioned above, according to the embodiment of the third inventive aspect, the rotation of ring 26 at variable speeds allows the strength of multi-pole magnetic field around the wafer W within the vacuum chamber 1 to be set at an appropriate level and at a very weak level (preferably approximately one half of the former level).

Accordingly, when etching is performed on a silicon dioxide film in the presence of a multi-pole magnetic field, the etch rate uniformity across the surface of the wafer can be improved. On the other hand, when etching is performed on an organic low-dielectric (low-K value) film and the like in the absence of multi-pole magnetic field, the etch rate uniformity across the surface of the wafer can also be improved.

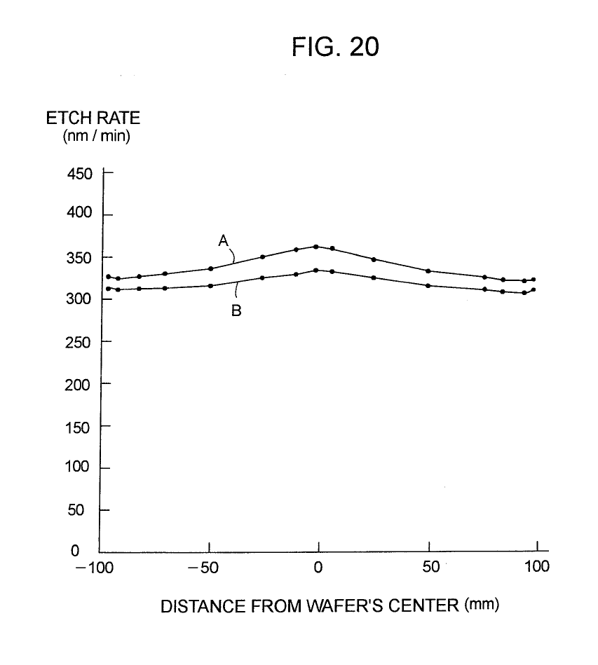

FIGS. 20 to 22 are graphic representations for showing experimental results of etch uniformity conducted under different conditions, wherein etch rates are plotted as a function of the distance from the center of the wafer W. In each of these figures, the curve A indicates results obtained in the presence of a multi-pole magnetic field of strength 0.03 T (300 G), the curve B indicating results obtained in the presence of a multi-pole magnetic field of strength 0.08 T (800 G).

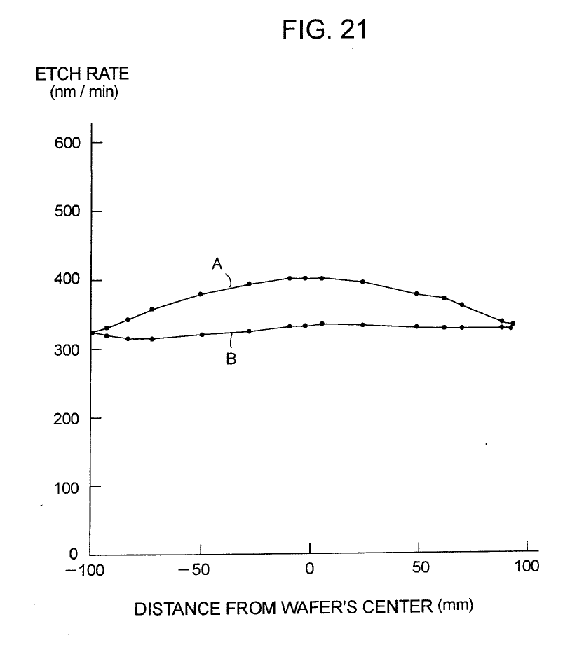

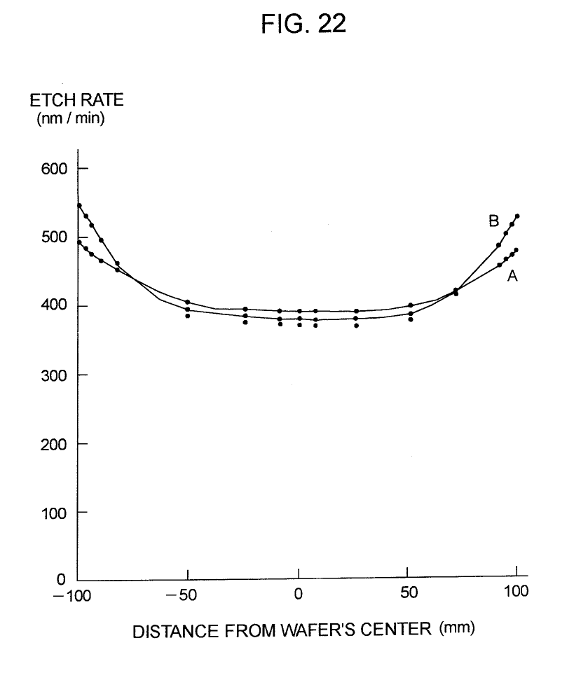

C₄F₈ gas is used for etching a silicon dioxide film to obtain the results of FIG. 20. CF₄ gas is used for etching a silicon dioxide film to obtain the results of FIG. 21, and a mixture of N₂ and H₂ gases is used for etching an organic low-dielectric (Low-K) film to obtain the results of FIG. 22. As indicated in FIGS. 20 and 21 where the process gas contains carbon (C) and fluorine (F) as in C₄F₈ gas or CF₄ gas, it is seen that the etch rate is substantially uniform in the presence of a strong multi-pole magnetic field. On the other hand, as shown in FIG. 22, when a mixture of N₂ and H₂ gases is used for etching the organic low-dielectric film, the etch rate becomes substantially uniform in the presence of weak multi-pole magnetic field.

As mentioned above, according to the embodiment of the third inventive aspect, the rotation control of conductive ring 26 causes the strength of multi-pole magnetic field within the vacuum chamber 1 to be easily set at an optimum level for wafer processing.

It is noted that the conductive ring 26 may be formed of a material that is not limited to aluminum, but may include non-magnetic materials having a high conductivity such as copper and brass. The thickness of the ring 26 is such that eddy currents can be easily sufficiently generated and that its mechanical strength is sufficient to withstand external force. For example, a thickness of 5 to 20 millimeters is satisfactory.

The multi-pole magnetic field generated in this way may cause localized scraping on the inner sidewall of the vacuum chamber 1 corresponding to the poles (as marked by the letter P in FIG. 18). In order to avoid this problem, the magnetic field generator 21 is revolved outside the vacuum chamber 1 using the rotary drive mechanism 25, whereby the localized damage can be prevented due to the movement of the magnetic poles.

While mention has been made of the embodiment of the third inventive aspect, which is applied to the etching apparatus for implementing etching on a semiconductor wafer, the present invention could equally be applied to other processes including plasma processing on a substrate such as a chemical vapor deposition (CVD) film forming process and the like.

As described above, according to the third inventive aspect, the multi-pole magnetic field is able to be easily controlled and maintained in a desired condition depending on the needs required by different plasma processing.

A fourth inventive aspect will be described.

A magnetron plasma processing apparatus, to which the fourth inventive aspect is applied, is equal to that of the first invention (FIG. 1), and as such, the apparatus is not illustrated and the description thereof will be omitted.

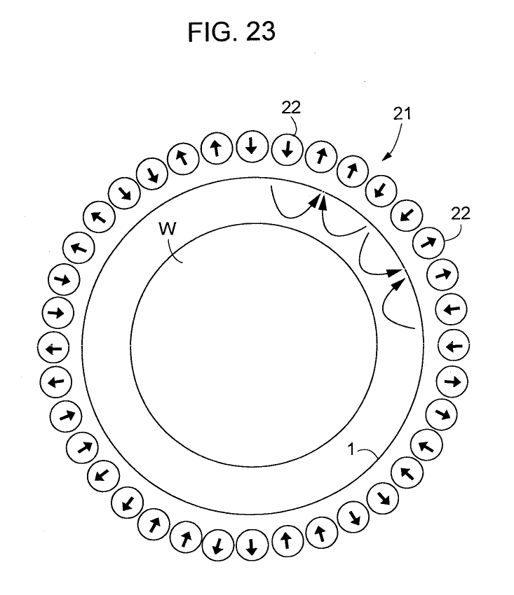

As shown in FIG. 23, the magnetic field generator 21 according to the fourth inventive aspect is comprised of a plurality of magnetic segments 22 (thirty-six in FIG. 23), which are held suing a supporting member (not shown). The adjacent magnetic segments form a single magnetic field pole. As shown in FIG. 23, the magnetic segments are respectively oriented to the vacuum chamber 1 with the magnetic poles thereof being alternately opposite, and thus a total of eighteen magnetic field poles are formed in this case.

It is understood from FIG. 23 that the multi-pole magnetic field is formed around the circumference of the semiconductor wafer W, and there exist substantially zero magnetic force over the wafer W.

Although the magnetic field strength above the wafer W is preferably zero, some value of field strength is allowed if it causes no harmless effect on the semiconductor etching process.

According to the instant embodiment, each of the magnetic segments 22 of the magnetic field generator 21 is arranged to rotate about its own vertical axis. Further, the magnetic segments 22 are detachably mounted. If a wafer of different size is processed, part of the magnetic segments 22 is dismounted. In doing so, the multi-pole magnetic field of the magnetic field generator 21 is able to alter its multi-pole magnetic field pattern.

It is supposed, by way of example, that the arrangement of FIG. 23 is used to process a 12-inch wafer, wherein a multi-pole magnetic field is formed whose field poles are thirty-six in number. On the other hand, if an 8-inch wafer should be processed using the arrangement of FIG. 23, then the magnetic field generated in the vacuum chamber 1 is spaced too far from the periphery of the wafer W, and accordingly, it is difficult for such a magnetic field to satisfactorily confine plasma.

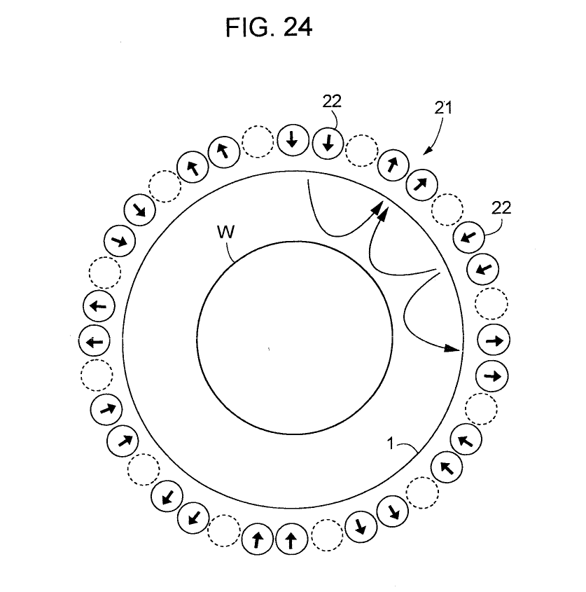

To avoid this problem, part of the magnetic segments 22 is removed (as indicated by dotted circles) so that the total number of magnetic segments is reduced to twelve in the case shown in FIG. 24. Further, some of the other segments are rotated about their vertical axis to change the direction of their magnetized directions, as shown in FIG. 24. With this arrangement, the multi-pole magnetic field extends inwardly to the periphery of the 8-inch wafer W, whereby an appropriate plasma processing can be implemented on the wafer W.

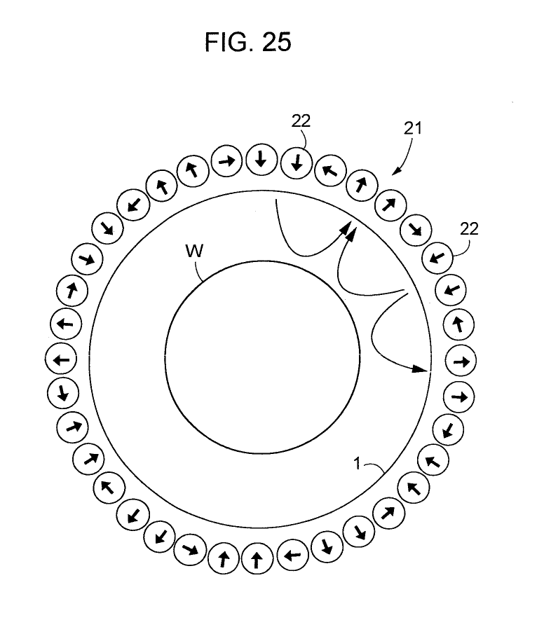

As an alternative to the above-mentioned removal of part of the magnetic segments 22 from the arrangement of FIG. 23, the same multi-pole magnetic field can be carried out as follows. That is to say, as shown in FIG. 25, the magnetic segments, which are positioned between magnetic field poles, are rotated so that their magnetized directions are oriented in circumferential directions opposite to the directions of the magnetic field poles, whereby it is possible to reduce the number of magnetic field poles without removing some of the magnetic segments.

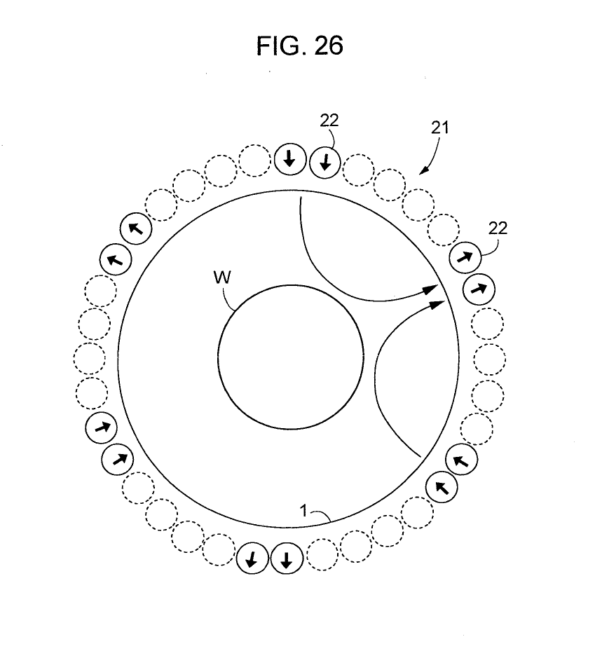

A further variant is shown in FIG. 26. In this variant, part of the magnetic segments 22 are simply removed (as marked by dotted circles) so that the total number of the magnetic field poles is reduced to 6, in the case of which the magnetic field further extends inwardly into the vacuum chamber.

In addition, instead of removing magnetic segments, magnetic members such as iron may be provided between the magnetic segments 22 that are indicated by dotted circles (shown in FIG. 26) and the vacuum chamber 1, as shown in FIG. 26. By the provision of such magnetic members, it is possible to extend the magnetic field inwardly into the vacuum chamber as in the case shown in FIG. 26.

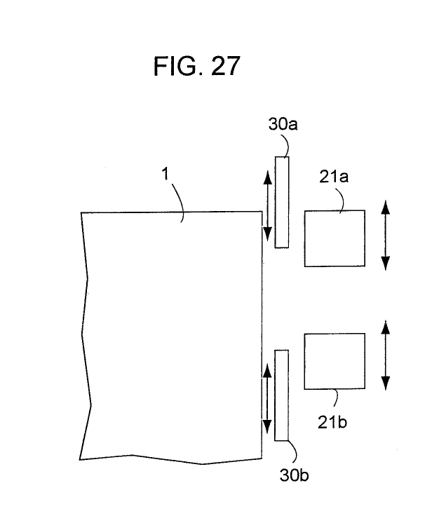

In FIG. 27, a further modification of the magnetic field generator is illustrated. In this modification, the magnetic field generator is comprised of an upper magnetic field generator 21a and a lower magnetic generator 21b. Both generators 21a and 21b are vertically movably. As a result, the strength of the multi-pole magnetic field generated in the vacuum chamber 1 is able to be controlled.

Still further, upper and lower magnetic members 30a and 30b, which are respectively made of material such as iron and are formed cylindrically, are vertically movably arranged between the magnetic field generators 21a and 21b and the vacuum chamber 1. By moving the magnetic cylindrical members 30a and 30b relative to each other to alter their mutual spacing, the strength of the multi-pole magnetic field can be controlled. It is possible to vertically move both the members 30a-30b and the magnetic generators 21a and 21b.

With the addition of the magnetic members 30a and 30b, the magnetic field control can be achieved by smaller vertical displacement of the magnetic field generators 21a and 21b.

According to the present invention, if necessary, the strength of the multi-pole magnetic field can be controlled during the time for which the wafer processing is in progress. If the movable magnetic cylindrical members 30a and 30b are brought into contact with each other, the multi-pole magnetic field generated in the vacuum chamber 1 is substantially reduced to zero.

Note that the magnetic segments are provided in number that can be varied as desired. In the above example, two magnetic segments are used to form a single magnetic field pole. Only one magnetic segment can be used to form a magnetic field pole or three or more magnetic segments can be used to form a magnetic field pole.

While mention has been made of embodiments in which the present invention is applied to wafer etching, the present invention could equally be applied to other processes including plasma processing such as CVD film forming process.

1. A magnetic field generator for magnetron plasma, comprising a plurality of magnetic segments provided on the outer side of a process chamber for performing a predetermined process on a substrate placed in said chamber, for generating a multi-pole magnetic field along the circumference of said substrate, characterized in that the arrangement is such that a strength of said multi-pole magnetic field in said process chamber can be controlled, and in that first ones of said plurality of magnetic segments are rotatably mounted so that their directions of magnetic fields can be altered and in that second, remaining ones of said plurality of magnetic segments are stationary magnetic segments.

2. A magnetic field generator as claimed in claim 1, characterized in that the magnetic fields of said stationary magnetic segments are pointing to the center of said process chamber.
